(19) United States
(12) Patent Application Publication
(10) Pub. No.: US 2011/0043191 A1
(43) Pub. Date: Feb. 24, 2011

(54) Phoenix probe X voltage tester

(76) Inventor: Fidel Gutierrez, San Bernardino, CA (US)

Correspondence Address: RUTH EURE, 4795 EDISON AVENUE, BOULDER, CO, 80301, US

(21) Appl. No.: 12/661,100

(22) Filed: Mar. 10, 2010

Related U.S. Application Data
(60) Provisional application No. 61/209,660, filed on Mar. 10, 2009.

(51) Int. Cl. G01R 13/00

(52) U.S. Cl. 324/140 R

(57) ABSTRACT

The present invention a cordless power tester that is capable of reading multiple input and output voltage. This tool will provide a mechanic or electrician with all the information that is needed when searching for a short circuit, or other circuit interruption in an electrical circuit. When such a short is located, indicated where the problem is located. The Phoenix Probe X is easy to use and easy to read.

### CLAIM OF PRIORITY

This patent application claims priority under 35 USC 119 (e) (1) from U.S. Provisional Patent Application Ser. No. 61/209,660 filed Mar. 10, 2009, of common inventorship and title herewith.

### FIELD OF THE INVENTION

The present invention pertains to the field of electrical testing devices, and more specifically to the field of portable electrical circuitry voltage testers.

### BACKGROUND OF THE INVENTION

The prior art has put forth several designs for portable electrical circuitry voltage testers. Among these are:

U.S. Pat. No. 4,112,748 to Richard J. Walley describes an automatic portable solid state voltage regulator tester specifically made for testing Ford and General Motors regulators. This is a tester made to test voltage regulators in the aforementioned American made automobiles.

U.S. Pat. No. 4,366,434 to Tony Ellis describes voltage detectors and electrical continuity checkers in the form of a pencil having a needle capable of piercing electrical insulation, a pair of light emitting diodes for determining polarity of the voltage, a third light emitting diode and associated circuitry to perform a continuity check, a flexible cable and chip which can be plugged into the pencil to perform either one of the tests in conjunction with the needle, and biasing arrangements for the light emitting diodes in order to lower their threshold of conduction.

U.S. Pat. No. 4,634,971 to Robert C. Johnson, David L. Perry, and Bernd E. Peitsch describes a portable hand-held voltage sensor with manually adjustable reference voltage for comparison with sensed voltage comprising a low impedance test lamp mode or a high impedance voltage test mode selectable via a thumb accessed slide switch.

None of these prior art references describe the present invention.

### SUMMARY OF THE INVENTION

It is an object of the present invention to provide an improved cordless power tester capable of reading multiple voltage inputs and outputs.

### BRIEF DESCRIPTION OF THE DRAWINGS

FIG. 1 is a front perspective view of various components which comprise the device of the present invention.

FIG. 2 is front perspective view of the main unit of the present invention showing the multi volt meter display.

FIG. 3 is front perspective view of the main unit of the present invention showing the 2 color light display, battery and other lights.

FIG. 4 is a diagrammatic representation of the device of the present invention.

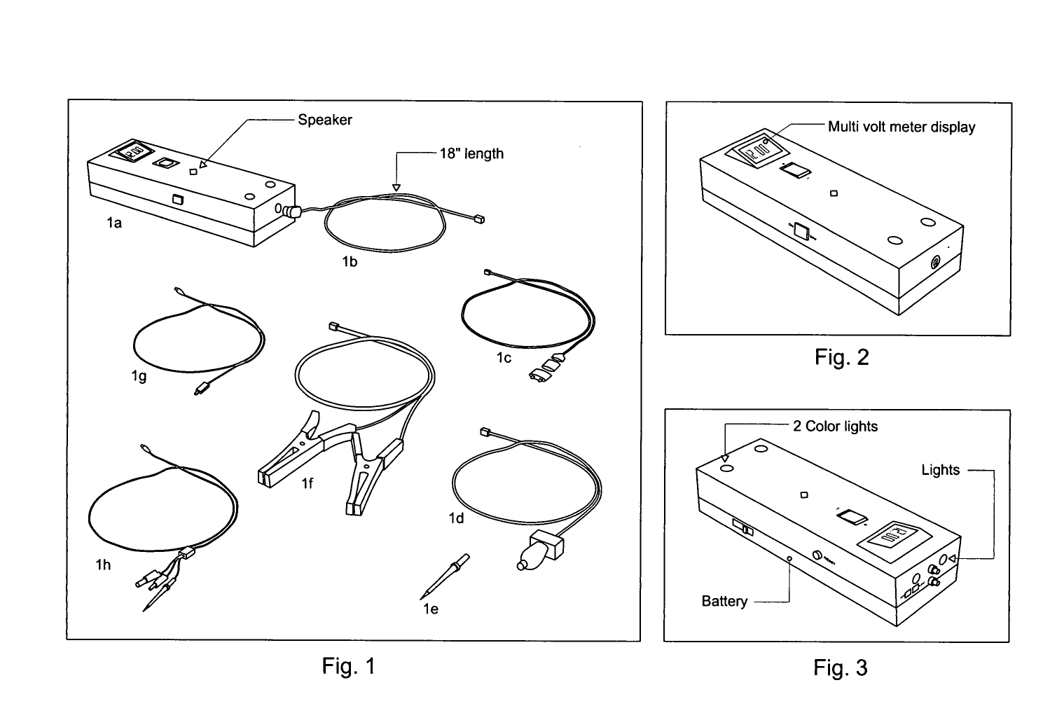

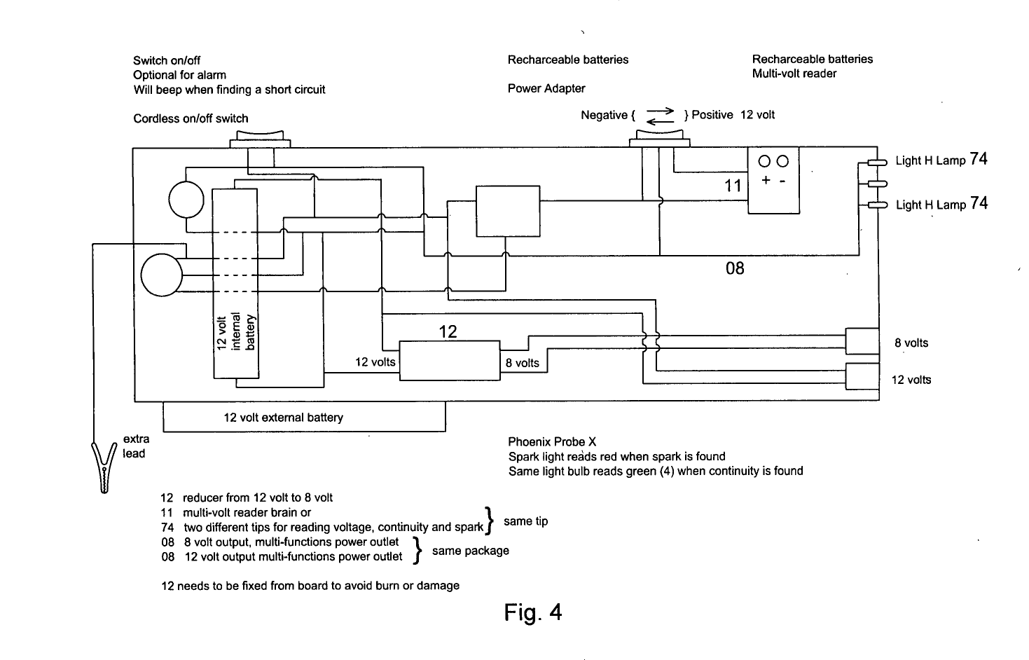

### DETAILED DESCRIPTION OF THE INVENTION

The present invention, hereinafter referred to as the Phoenix Probe X, is a cordless power tester that is capable of reading multiple input and output voltage. This tool will provide a mechanic or electrician with all the information that is needed when searching for a short circuit, or other circuit interruption in an electrical circuit. When such a short is located, indicated where the problem is located. The Phoenix Probe X is easy to use and easy to read. It will save the consumer money by enabling him to test the power source on such items as power seats, car radios, power window regulators, starters, electric fans, speakers, fuel injectors, and other electrical devices.

The Phoenix Probe X is portable and can be used at such places as automobile auctions, auto-wrecking facilities and dismantling yards, saving the consumer valuable time and money on purchasing parts that may or may not work. The benefits to automobile mechanics and electricians are countless. The functionality and size of the Phoenix Probe X provides a fast and effective way to check a power source. It is cordless and uses a rechargeable battery. There is no need for any extension cords or power outlets. The display has a digital screen and is easy to read. The Phoenix Probe X is a unique tool for all automobile and electrical professionals as well as for the do-it-yourself individual.

The Phoenix Probe X features a cordless battery pack and a 12 volt rechargeable battery. The Phoenix Probe X can also be used as a power source with 8 and 12 volt voltage outputs.

The Phoenix Probe X comprises a digital voltmeter and an LCD screen, breaker re-set button, injector (positive or negative), an alarm or buzzer, and a dual color indicator light bulb for a conventional test of fuses or for circuit continuity. An additional ground output with grip is included as well as an on/off switch.

The Phoenix Probe X also features a spark finder, pulsation detector, cigarette lighter AC adapter, tool belt or wrist strap, built-in flash light and more, all in this easy to use power tester.

Various interchangeable snap on plug wires are included to allow the user to switch from job to job easily and in little time. The Phoenix Probe X is able to test speaker wire to find which is positive and which is negative.

When looking for a short and a short is detected, the Phoenix Probe X shuts off automatically.

The Phoenix Probe X can detect a spark on a spark plug wire, or it can detect a misfire or a damaged wire and illuminate an indicator light if any of these conditions is detected.

The Phoenix Probe X can also detect pulsation in a fuel injector by touching the negative contact point and holding the positive contact point with a grip. If a pulsation is detected, an indicator light will illuminate.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claims.

1. An improved multi-function voltage tester comprising:
a cordless battery pack and a 12 volt rechargeable battery;
a power source having both 8 volt and 12 volt voltage outputs;
a digital voltmeter;
an LCD screen;
a breaker re-set button,
an injector (positive or negative);
an alarm or buzzer;
a dual color indicator light bulb;
an additional ground output with grip; and
an on/off switch.

2. The improved multi-function voltage tester of claim 1 further comprising:
a spark finder;
a pulsation detector;
an AC adapter for a cigarette lighter;
a tool belt or wrist strap; and
a built-in flash light.

3. The improved multi-function voltage tester of claim 1 further comprising:
various interchangeable snap on plug wires.

4. A method of testing the integrity of an electrical circuit using the improved multi-function voltage tester of claim 1.
